(19) United States
(12) Patent Application Publication
(10) Pub. No.: US 2013/0039012 A1
(43) Pub. Date: Feb. 14, 2013

(54) HEAT DISSIPATION DEVICE

(71) Applicants: CHUAN-FENG SHIH, KAOHSIUNG (TW); JON-LIAN KWO, KAOHSIUNG (TW); SHENG-WEN FU, KAOHSIUNG CITY (TW); HSUAN-TA WU, KAOHSIUNG (TW)

(72) Inventors: CHUAN-FENG SHIH, KAOHSIUNG (TW); JON-LIAN KWO, KAOHSIUNG (TW); SHENG-WEN FU, KAOHSIUNG CITY (TW); HSUAN-TA WU, KAOHSIUNG (TW)

(73) Assignee: ALL REAL TECHNOLOGY CO., LTD., KAOHSIUNG CITY (TW)

(21) Appl. No.: 13/568,560

(22) Filed: Aug. 7, 2012

(30) Foreign Application Priority Data
Aug. 8, 2011 (TW) 100128098
May 18, 2012 (TW) 101117917

(51) Int. Cl. H05K 7/20

(52) U.S. Cl. 361/700

(57) ABSTRACT

The present invention relates to a heat dissipation device, including at least one semiconductor device, at least one first substrate and a cooling substance. The first substrate has a first surface, a second surface and at least one hole, wherein the semiconductor device is located on the first surface of the first substrate, and the hole is opened at the second surface of the first substrate and corresponds to the semiconductor device. The cooling substance is used for flowing in the hole and taking away heat from the semiconductor device, wherein the cooling substance is in contact with the first substrate. Thereby, the temperature of the semiconductor device can be reduced efficiently.

### BACKGROUND OF THE INVENTION

1. Field of the Invention

The present invention relates to a heat dissipation device, and more particularly, to a heat dissipation device for dissipating heat from a semiconductor device.

2. Description of the Related Art

In order to improve efficiency of semiconductor devices, more and more semiconductor devices develop toward high power, such as high brightness light emitting diode (LED), high concentrator photovoltaic (HCPV) cell, power amplifier (PA), bipolar transistor, high electron mobility transistor (HEMT), photosensitive diode, laser diode and integrated circuit (IC) device.

Since a high-power semiconductor device usually generate a large amount of heat during operation, the performance and lifetime of the semiconductor device is lowered if the heat cannot be dissipated in time. A high operating temperature of a semiconductor device may cause problems such as poor operating efficiency and color drift of the LED. Specifically, the heat dissipation capability is very important to the HCPV cell and the high-power LED. Therefore, the high-power semiconductor device is required to dissipate heat rapidly and efficiently.

FIG. 1 is a schematic cross sectional view of a conventional heat dissipation device. The heat dissipation device 1 includes a semiconductor device, which is an LED device 10, a substrate 12, a container 16 and a cooling liquid (or flowing substance) 14. The substrate 12 is a package substrate, and has a first surface 121 and a second surface 122. The LED device 10 is located at the first surface 121 of the substrate 12. The second surface 122 of the substrate 12 is located on the container 16. The cooling liquid (or flowing substance) 14 flows in the container 16, so as to take away the heat generated by the LED device 10 during light emission.

The conventional heat dissipation device 1 has the following defects. The heat of the LED device 10 enters the cooling liquid (or flowing substance) 14 only after the heat passes through the substrate 12 and sidewalls of the container 16, so as to be taken away by the cooling liquid (or flowing substance) 14. Excessive thermal resistance exists between the LED device 10 and the cooling liquid (or flowing substance) 14 since the substrate 12 and the container 16 are disposed therebetween. Thus, the heat of the LED device 10 cannot be rapidly conducted to the cooling liquid 14, resulting in that the heat dissipation efficiency of the conventional heat dissipation device 1 is not high. That is, the thermal resistance of the prior art is too large. In actual measurement, the light emitting power of the LED device 10 is 3 W, the temperature of the cooling liquid 14 is 35° C., the measured junction temperature is 51.2° C., and the thermal resistance is 7.7° C./W. The junction temperature refers to the temperature of a contact surface (namely the first surface 121) between the LED device 10 and the substrate 12.

### SUMMARY OF THE PRESENT INVENTION

The present invention is directed to a heat dissipation device, comprising at least one semiconductor device, at least one first substrate and a cooling substance. The first substrate has a first surface, a second surface and at least one hole, wherein the semiconductor device is located on the first surface of the first substrate, and the hole is opened at the second surface of the first substrate and corresponds to the semiconductor device. The cooling substance is used for flowing in the hole and taking away heat from the semiconductor device, wherein the cooling substance is in contact with the first substrate. Thereby, the temperature of the semiconductor device can be reduced efficiently.

In one embodiment, the heat dissipation device further comprises a second substrate disposed on the second surface of the first substrate, wherein the second substrate has at least one through hole in communication with the at least one hole of the at least one first substrate, so that the cooling substance flows into the at least one hole through the at least one through hole.

In one embodiment, the heat dissipation device further comprises at least one container for accommodating the cooling substance, wherein the at least one container has an opening, the at least one hole of the at least one first substrate is in communication with the opening, so that the cooling substance flows into the at least one hole through the opening

In one embodiment, the heat dissipation device further comprises at least one soaking device, wherein the at least one soaking device includes at least one soaking device opening in communication with the at least one hole. The cooling substance absorbs the heat of the at least one semiconductor device so as to form a vapor to flow in the at least one soaking device.

### BRIEF DESCRIPTION OF THE DRAWINGS

FIG. 1 is a schematic cross sectional view of a conventional heat dissipation device;

FIG. 2 is a schematic cross sectional view of an embodiment of the heat dissipation device according to the present invention;

FIG. 3 is a schematic cross sectional view of another embodiment of the heat dissipation device according to the present invention;

FIG. 4 is a schematic cross sectional view of another embodiment of the heat dissipation device according to the present invention;

FIG. 5 is a schematic cross sectional view of another embodiment of the heat dissipation device according to the present invention;

FIG. 6 is a schematic view of another embodiment of the heat dissipation device according to the present invention;

FIG. 7 is a schematic view of another embodiment of the heat dissipation device according to the present invention;

FIG. 8 is a schematic exploded view of another embodiment of the heat dissipation device according to the present invention;

FIG. 9 is a schematic assembly view of FIG. 8;

FIG. 10 is a schematic view of another embodiment of the heat dissipation device according to the present invention;

FIG. 11 is a diagram illustrating a relation between wavelengths and intensities of light emitted by the LED device at different junction temperatures;

FIG. 12 is a diagram illustrating a relation between intensities and junction temperatures of blue light and yellow light of the LED device;

FIG. 13 is a diagram illustrating a relation between intensity ratios of blue light to yellow light of the LED device and junction temperatures;

FIG. 14 is a schematic perspective view of an embodiment of the heat dissipation device according to the present invention;

FIG. 15 is a schematic cross sectional view of FIG. 14;

FIG. 16 is a schematic enlarged view of an area A of FIG. 15;

FIG. 17 is a schematic cross sectional view of another embodiment of the heat dissipation device according to the present invention;

FIG. 18 is a schematic cross sectional view of another embodiment of the heat dissipation device according to the present invention;

FIG. 19 is a schematic cross sectional view of another embodiment of the heat dissipation device according to the present invention;

FIG. 20 is a schematic cross sectional view of another embodiment of the heat dissipation device according to the present invention;

FIG. 21 is a schematic cross sectional view of another embodiment of the heat dissipation device according to the present invention;

FIG. 22 is a schematic perspective view of an embodiment of the heat dissipation device according to the present invention;

FIG. 23 is a schematic partially enlarged view of FIG. 22;

FIG. 24 is a schematic perspective view of another embodiment of the heat dissipation device according to the present invention;

FIG. 25 is a diagram illustrating a relation between relative light output and lifetime of the LED device at different junction temperatures;

FIG. 26 is a schematic perspective view of another embodiment of the heat dissipation device according to the present invention;

FIG. 27 is a schematic view illustrating the heat dissipation device of FIG. 22 being assembled on a receiving plate;

FIG. 28 is a schematic view illustrating the heat dissipation device of FIG. 24 being assembled on a receiving plate; and

FIG. 29 is a schematic view illustrating the heat dissipation device of FIG. 26 being assembled on a receiving plate.

### DETAILED DESCRIPTION

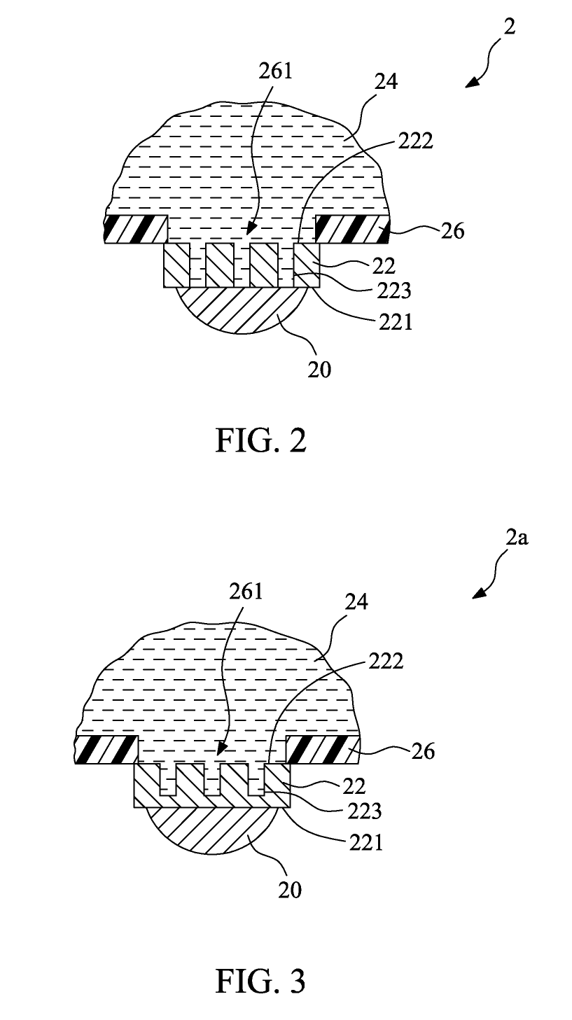

FIG. 2 is a schematic cross sectional view of an embodiment of the heat dissipation device according to the present invention. The heat dissipation device 2 comprises at least one semiconductor device 20, at least one first substrate 22 and a cooling substance 24. The semiconductor device 20 at least comprises, e.g., light emitting diode (LED), photosensitive diode, photovoltaic cell, solar cell, electro-luminance light emitting diode (EL LED), laser diode, power amplifier (PA), transistor or integrated circuit (IC) device. In this embodiment, the semiconductor device 20 is a light emitting diode (LED) device, and at least has a die (not shown). The first substrate 22 has a first surface 221, a second surface 222 and at least one hole 223. The semiconductor device 20 is located on the first surface 221 of the first substrate 22. The hole 223 is opened at the second surface 222 of the first substrate 22 and corresponds to the semiconductor device 20. The cooling substance 24 is used for flowing in the hole 223 and contacting the semiconductor device 20 and the first substrate 22, so as to take away the heat from the semiconductor device 20.

In this embodiment, the first substrate 22 has three holes 223; however, in other embodiments, the first substrate 22 may have one hole 223 only. The holes 223 are further opened at the first surface 221 of the first substrate 22. That is, the holes 223 penetrate through the first substrate 22, so that the cooling substance 24 can contact the semiconductor device 20 after entering the holes 223 through the second surface 222 of the first substrate 22, so as to directly take away the heat from the semiconductor device 20.

In this embodiment, the first substrate 22 is a package substrate, and the material thereof is resin. The cooling substance 24 at least includes water, methanol, ethanol, acetone, ammonia, paraffin, oil, chlorofluorocarbons (CFCs), or other cooling substances such as 3M® Flourinert or 3M® Novec, or two or more mixture thereof.

Preferably, the heat dissipation device 2 further includes at least one container 26, for accommodating the cooling substance 24. The container 26 has an opening 261. The holes 223 of the first substrate 22 are in communication with the opening 261, so that the cooling substance 24 can flow into the holes 223 through the opening 261.

In this embodiment, the semiconductor device 20 is an LED device, the light emitting power thereof is 3 W, the cooling substance 24 is water with a temperature of 35° C., the measured junction temperature is 45° C., and the thermal resistance is 4.7° C./W. The junction temperature refers to the temperature of a contact surface (namely the first surface 221) between the semiconductor device 20 and the first substrate 22. As compared with the prior art, the present invention can efficiently reduce the temperature of the semiconductor device 20, thereby improving the heat dissipation efficiency.

FIG. 3 is a schematic cross sectional view of another embodiment of the heat dissipation device according to the present invention. The heat dissipation device 2a of this embodiment is substantially similar to the heat dissipation device 2 of FIG. 2, and the same elements are designated with the same reference numerals. The difference between the heat dissipation device 2a of this embodiment and the heat dissipation device 2 of FIG. 2 lies in that, in this embodiment, the holes 223 are blind holes. That is, the holes 223 are not opened at the first surface 221 of the first substrate 22.

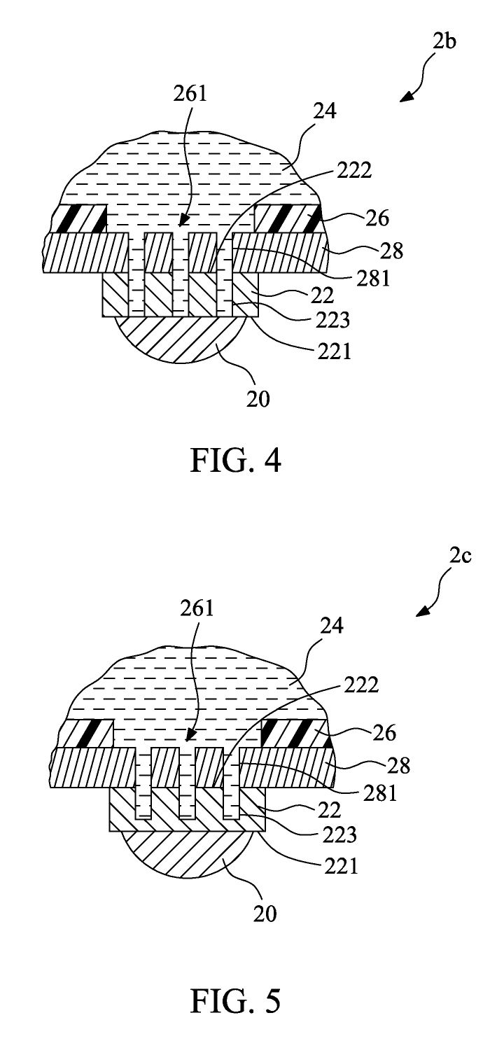

FIG. 4 is a schematic cross sectional view of another embodiment of the heat dissipation device according to the present invention. The heat dissipation device 2b of this embodiment is substantially similar to the heat dissipation device 2 of FIG. 2, and the same elements are designated with the same reference numerals. The difference between the heat dissipation device 2b of this embodiment and the heat dissipation device 2 of FIG. 2 lies in that, in this embodiment, the heat dissipation device 2b further comprises a second substrate 28. The material of the second substrate 28 is aluminum, copper or ceramic The second substrate 28 is a heat dissipating substrate or a circuit board, and is disposed between the second surface 222 of the first substrate 22 and the container 26. The second substrate 28 has at least one through hole 281. In this embodiment, the second substrate 28 has three through holes 281. The through holes 281 are in communication with the holes 223 of the first substrate 22, so that the cooling substance 24 can flow into the holes 223 through the through holes 281.

FIG. 5 is a schematic cross sectional view of another embodiment of the heat dissipation device according to the present invention. The heat dissipation device 2c of this embodiment is substantially similar to the heat dissipation device 2b of FIG. 4, and the same elements are designated with the same reference numerals. The difference between the heat dissipation device 2c of this embodiment and the heat dissipation device 2b of FIG. 4 lies in that, in this embodiment, the holes 223 are blind holes. That is, the holes 223 are not opened at the first surface 221 of the first substrate 22.

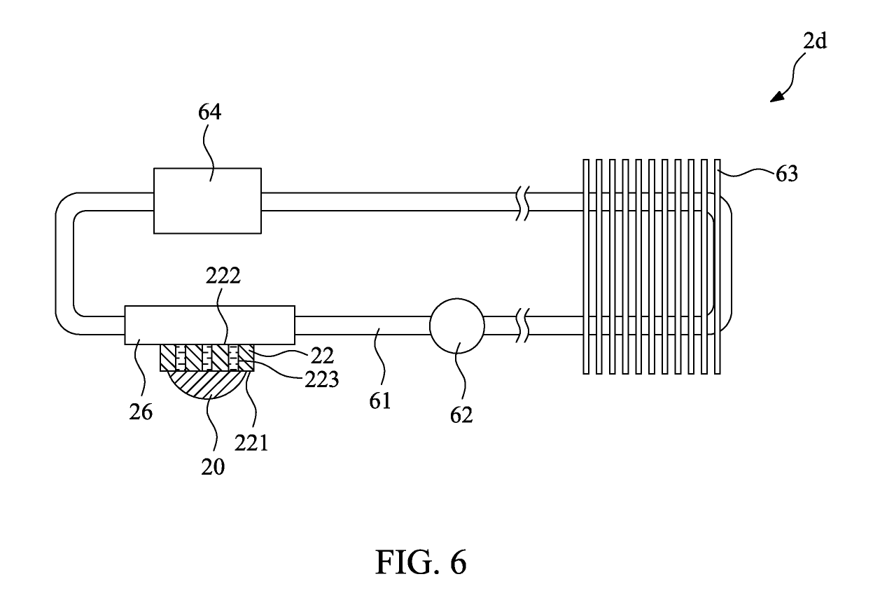

FIG. 6 is a schematic view of another embodiment of the heat dissipation device according to the present invention. The heat dissipation device 2d of this embodiment is substantially similar to the heat dissipation device 2 of FIG. 2, and the same elements are designated with the same reference numerals. The difference between the heat dissipation device 2d of this embodiment and the heat dissipation device 2 of FIG. 2 lies in that, in this embodiment, the container 26 is a water-cooling head, and the heat dissipation device 2d further comprises a circulation pipeline 61, a pump 62, and a plurality of heat dissipation fins 63.

The circulation pipeline 61 connects two ends of the container 26 to form a closed loop, so that the cooling substance 24 flows in the formed closed loop. The pump 62 is located on the circulation pipeline 61, for providing kinetic energy required by the cooling substance 24 during flowing. The heat dissipation fins 63 are located on the circulation pipeline 61, for dissipating heat of the cooling substance 24, so as to obtain a better heat dissipation effect. Preferably, the heat dissipation device 2d further comprises an accommodation tank 64 located on the circulation pipeline 61, for storing the cooling substance 24.

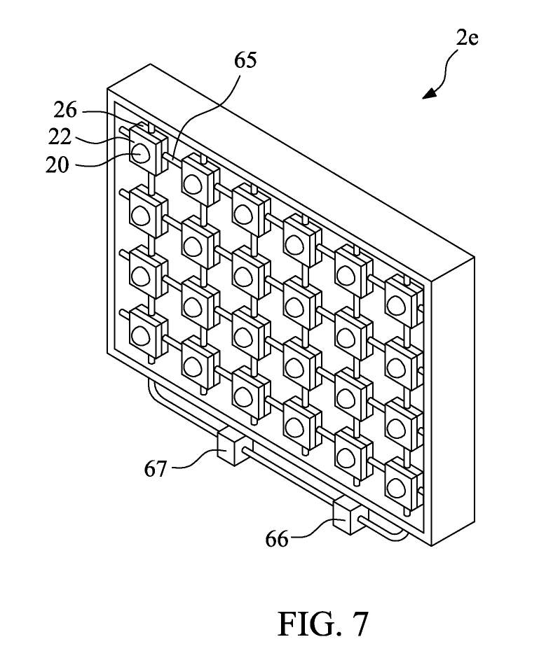

FIG. 7 is a schematic view of another embodiment of the heat dissipation device according to the present invention. The heat dissipation device 2e of this embodiment is substantially similar to the heat dissipation device 2d of FIG. 6, and the same elements are designated with the same reference numerals. The difference between the heat dissipation device 2e of this embodiment and the heat dissipation device 2d of FIG. 6 lies in that, in this embodiment, the number of the semiconductor device 20 is plural, the number of the first substrate 22 is plural, and the number of the container 26 is plural. Each of the semiconductor devices 20 is disposed on each of the first substrates 22, and each of the first substrates 22 is disposed on each of the containers 26.

The heat dissipation device 2e further comprises a connection pipeline 65 and a pump 66. The connection pipeline 65 connects the containers 26, and the pump 66 is located on the connection pipeline 65, for providing kinetic energy required by the cooling substance 24 during flowing. Preferably, the heat dissipation device 2e further comprises an accommodation tank 67 located on the circulation pipeline 65, for storing the cooling substance 24. Similarly, the additional technical features in FIG. 6 and FIG. 7 may be applied to the heat dissipation device 2 in FIG. 2, and certainly, these additional technical features may be also applied to the heat dissipation devices 2a, 2b and 2c in FIG. 3, FIG. 4 and FIG. 5, which is not repeated herein.

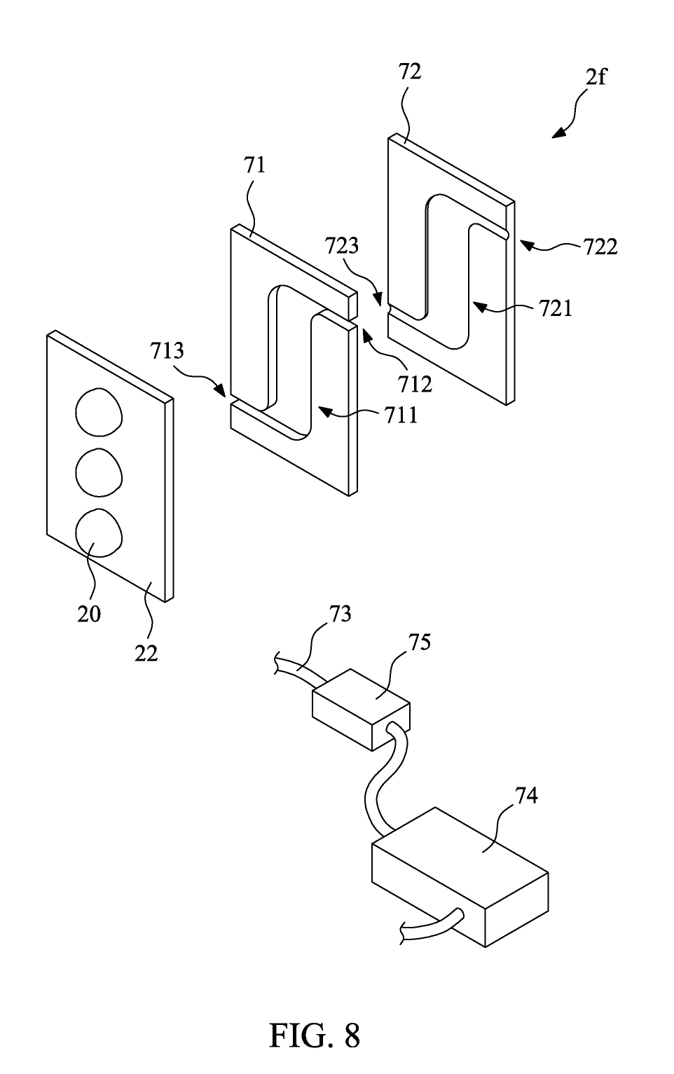

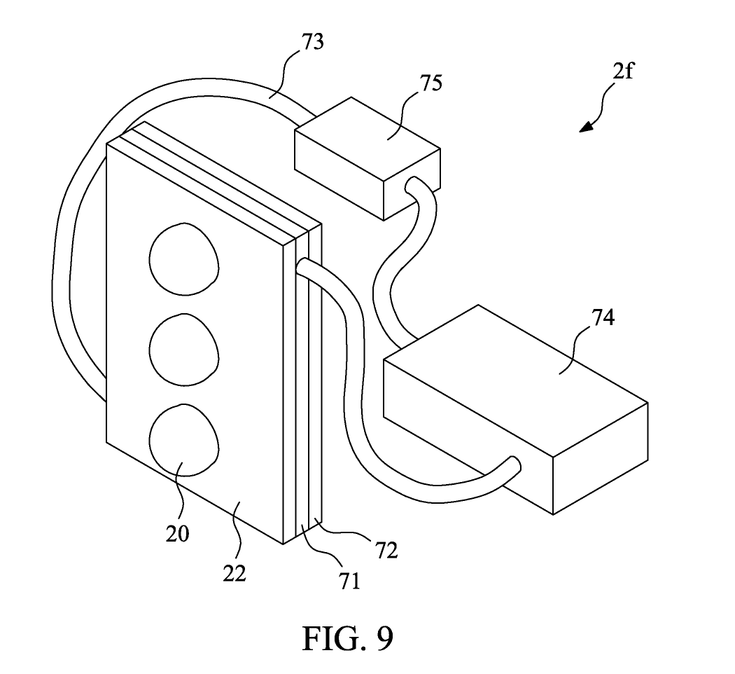

FIG. 8 and FIG. 9 are schematic exploded and assembly views of another embodiment of the heat dissipation device according to the present invention. The heat dissipation device 2f of this embodiment is substantially similar to the heat dissipation device 2 of FIG. 2, and the same elements are designated with the same reference numerals. The difference between the heat dissipation device 2f of this embodiment and the heat dissipation device 2 of FIG. 2 lies in that, in this embodiment, the container includes a base plate 72 and a middle plate 71. That is, the container is of a dual-layer structure. The base plate 72 has a center groove 721, an inlet slot 722 and an outlet slot 723. The inlet slot 722 and the outlet slot 723 are in communication with the center groove 721. The middle plate 71 is sandwiched between the first substrate 22 and the base plate 72. The middle plate 71 has an opening 711, an inlet 712 and an outlet 713. The opening 711, the inlet 712 and the outlet 713 penetrate through the middle plate 71. The inlet 712 and the outlet 713 are in communication with the opening 711. The opening 711, the inlet 712 and the outlet 713 respectively correspond to the center groove 721, the inlet slot 722 and the outlet slot 723. The hole (not shown) of the first substrate 22 is in communication with or corresponds to the opening 711.

The heat dissipation device 2f further comprises a connection pipeline 73, a pump 74 and an accommodation tank 75. The connection pipeline 73 connects the inlet 712 and the outlet 713 to form a closed loop, so that the cooling substance 24 flows in the closed loop. The pump 74 is located on the connection pipeline 73, for providing kinetic energy required by the cooling substance 24 during flowing. The accommodation tank 75 is located on the connection pipeline 73, for storing the cooling substance 24. Preferably, if the center groove 721, the inlet slot 722 and the outlet slot 723 of the base plate 72 are sufficiently deep, it is feasible that only the base plate 72 is used to connect the first substrate 22.

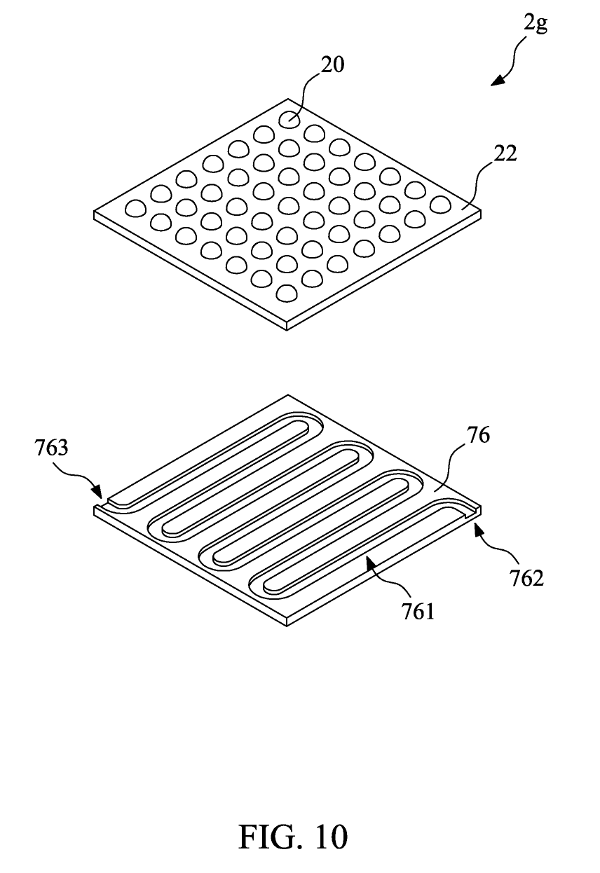

FIG. 10 is a schematic view of another embodiment of the heat dissipation device according to the present invention. The heat dissipation device 2g of this embodiment is substantially similar to the heat dissipation device 2f of FIG. 8, and the same elements are designated with the same reference numerals. The difference between the heat dissipation device 2g of this embodiment and the heat dissipation device 2f of FIG. 8 lies in that, in this embodiment, the container is a base plate 76 having an opening 761, and the opening 761 is a bending long trench which forms an inlet 762 and an outlet 763 at edges of the base plate 76.

A plurality of the semiconductor devices 20 is arranged on the first substrate 22 by means of array. The hole (not shown) of the first substrate 22 is in communication with or corresponds to the opening 761.

Similarly, the heat dissipation device 2g may further comprise a connection pipeline (not shown), a pump (not shown) and an accommodation tank (not shown). The connection pipeline connects the inlet 762 and the outlet 763 to form a closed loop, so that the cooling substance 24 flows in the closed loop. The pump is located on the connection pipeline, for providing kinetic energy required by the cooling substance 24 during flowing. The accommodation tank is located on the connection pipeline, for storing the cooling substance 24. Similarly, the additional technical features of FIG. 8, FIG. 9 and FIG. 10 may be applied to the heat dissipation device 2 in FIG. 2, and certainly, these additional technical features may also be applied to the heat dissipation devices 2a, 2b and 2c of FIG. 3, FIG. 4 and FIG. 5, which is not repeated herein.

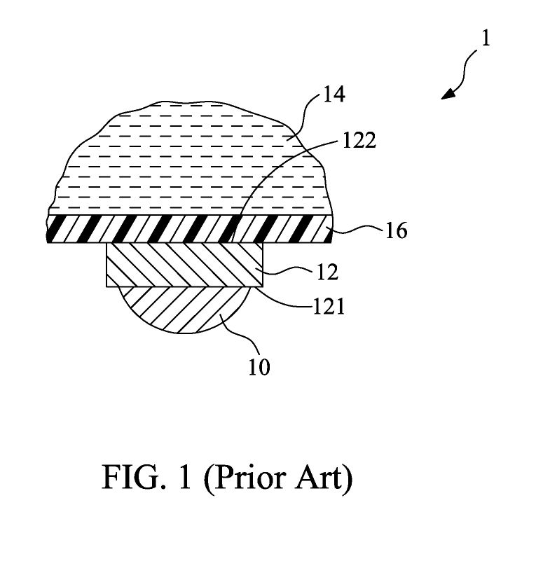

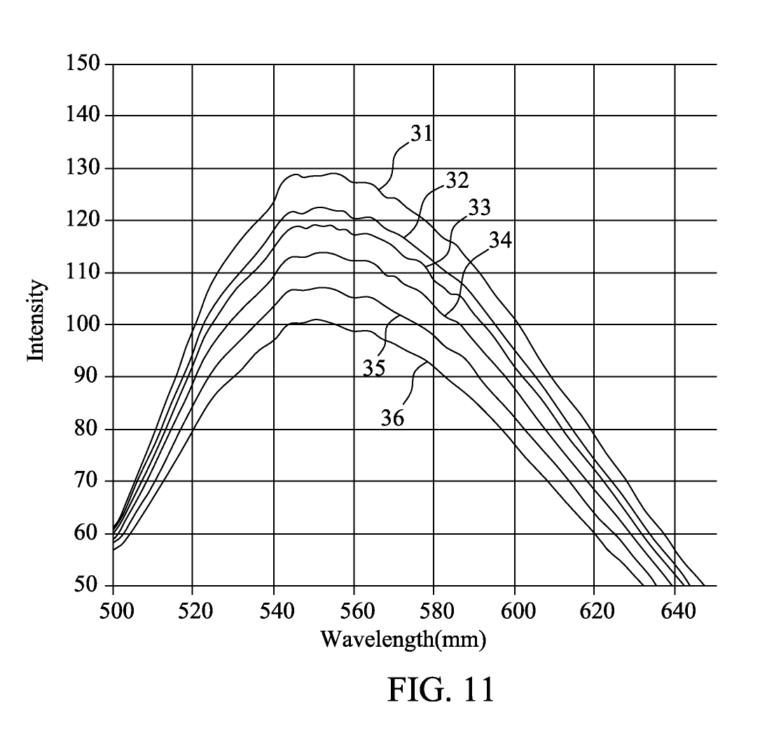

FIG. 11 is a diagram illustrating a relation between wavelengths and intensities of light emitted by the LED device at different junction temperatures, wherein the reference numeral 31 denotes a curve of 50.4° C., the reference numeral 32 denotes a curve of 51.9° C., the reference numeral 33 denotes a curve of 63.7° C., the reference numeral 34 denotes a curve of 72.0° C. , the reference numeral 35 denotes a curve of 82.8° C. and the reference numeral 36 denotes a curve of 87.1° C. In the present invention, the junction temperature refers to the temperature of a contact surface between the LED device (the semiconductor device 20) and the first substrate 22. Taking FIG. 1 for example, the junction temperature refers to the temperature of a contact surface (namely the first surface 121) between the LED device 10 and the substrate 12. Taking FIG. 2 to FIG. 5 for example, the junction temperature refers to the temperature of a contact surface (namely the first surface 221) between the LED device (the semiconductor device 20) of the first substrate 22. As shown in FIG. 11, if the temperature of the LED device is reduced from 87.1° C. to 50.4° C., the light emitting intensity of a particular wavelength (550 nm) can be raised by about 30%. In other words, the higher the junction temperature of the LED device (the semiconductor device 20) is, the worse the heat dissipation effect is, thus, the light emitting intensity thereof naturally cannot maintain and a slowly decaying state occurs. Incidentally, the unit of the vertical axis of FIG. 11 is any unit, that is, FIG. 11 only indicates relative intensities of corresponding wavelengths at different temperatures.

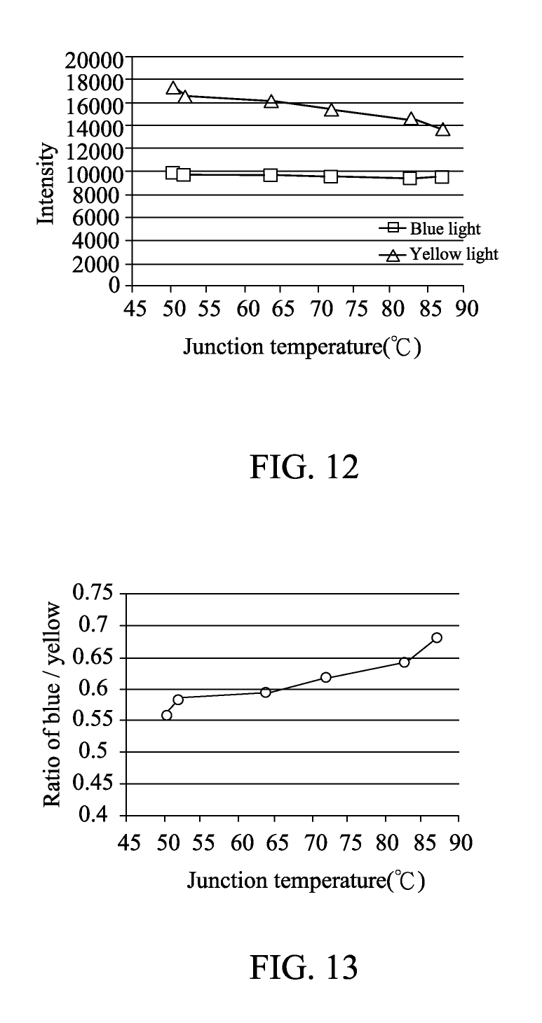

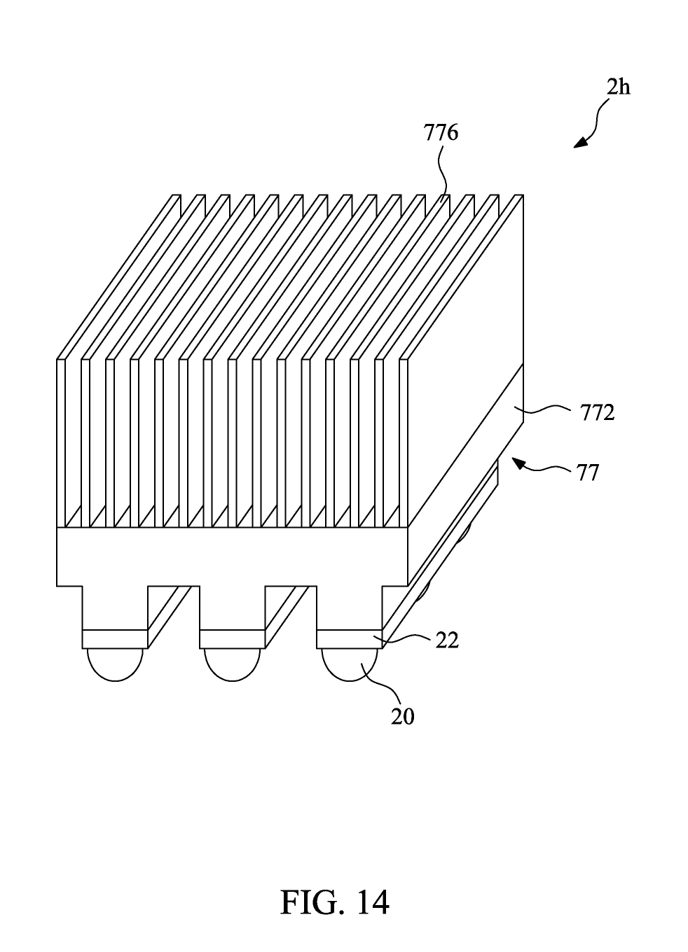

FIG. 12 is a diagram illustrating a relation between intensities and junction temperatures of blue light and yellow light of the LED device, wherein □ denotes the blue light, and A denotes the yellow light. A shown in FIG. 12, the higher the junction temperature is, the lower the intensity of the yellow light is, but the intensity of the blue light does not vary significantly. Further, FIG. 13 is a diagram illustrating a relation between intensity ratios of blue light to yellow light of the LED device and junction temperatures. As shown in FIG. 13, the higher the junction temperature is, the higher ratio of the blue light is; therefore, the light emitted by the LED device at high temperatures is bluish, which is not caused by increase of intensity of the blue light but by attenuation of intensity of the yellow light.

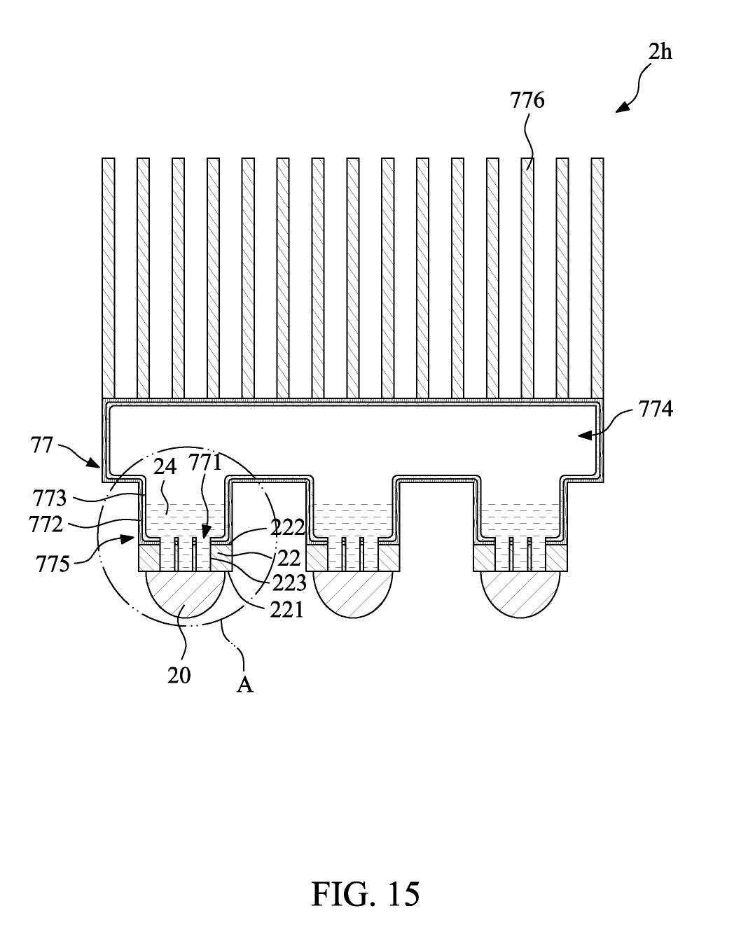

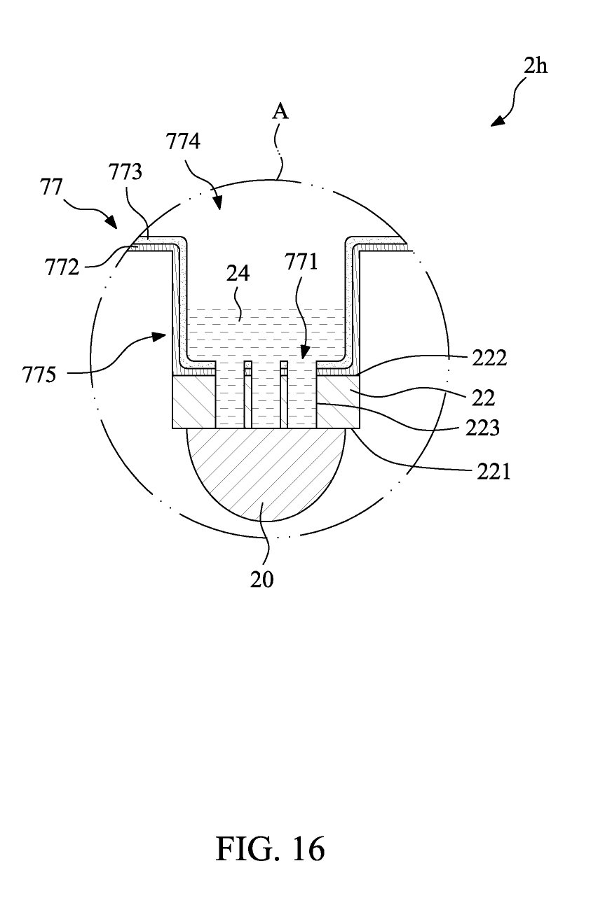

FIG. 14 is a schematic perspective view of an embodiment of the heat dissipation device according to the present invention. FIG. 15 is a schematic cross sectional view of FIG. 14. FIG. 16 is a schematic enlarged view of an area A of FIG. 15. The heat dissipation device 2h of this embodiment is substantially similar to the heat dissipation device 2 of FIG. 2, and the same elements are designated with the same reference numerals. The difference between the heat dissipation device 2h of this embodiment and the heat dissipation device 2 of FIG. 2 lies in that, in this embodiment, the heat dissipation device 2h comprises a soaking device 77, for example, a heat pipe. The soaking device 77 includes at least one soaking device opening 771, and the soaking device opening 771 is in communication with the hole 223. The cooling substance 24 is located in the hole 223 and absorbs the heat of the semiconductor device 20, so as to form a vapor to flow in the soaking device 77.

In this embodiment, the first substrate 22 has three holes 223, and the soaking device 77 has three soaking device openings 771; however, in other embodiments, the first substrate 22 may have one hole 223 only, and the soaking device 77 has one soaking device opening 771 only. The holes 223 are further opened at the first surface 221 of the first substrate 22. That is, the holes 223 penetrate through the first substrate 22, so that the cooling substance 24 can contact the semiconductor device 20 after entering the holes 223 through the soaking device openings 771 and the second surface 222 of the first substrate 22, so as to directly take away the heat from the semiconductor device 20. In conclusion, this embodiment is mainly characterized in reducing thermal resistance between the cooling substance 24 in the soaking device 77 and the semiconductor device 20, so that the heat dissipation effect of the cooling substance 24 in the soaking device 77 can be maximized.

In this embodiment, the soaking device 77 includes a shell body 772 and a capillary structure 773. The capillary structure 773 is located at inner sidewalls of the shell body 772 to define a hollow accommodation space 774. The soaking device opening 771 penetrate through the shell body 772 and the capillary structure 773 to be in communication with the hollow accommodation space 774. Therefore, the vapor formed by the cooling substance 24 can flow in the hollow accommodation space 774, thereby forming heat exchange with the external environment through the shell body 772, and finally condenses into the liquid state cooling substance 24. The condensed liquid cooling substance 24 flows back to the holes 223 through the capillary structure 773. Preferably, the material of the shell body 772 is metal (for example, brass, nickel, stainless steel, tungsten, aluminum, magnesium or other alloys), and the capillary structure 773 is a copper mesh, copper power sinter or trench.

In this embodiment, the soaking device 77 further includes at least one protrusion portion 775 and a plurality of heat dissipation fins 776. Each of the protrusion portions 775 protrudes from the bottom of the soaking device 77, and corresponds to each of the first substrates 22. The soaking device openings 771 are located at a lower side of the protrusion portion 775, and the capillary structure 773 and the hollow accommodation space 774 extend into the protrusion portion 775. The heat dissipation fins 776 are connected to upper outer sidewalls of the shell body 772 of the soaking device 77, so as to increase the heat dissipation efficiency.

The operation of the heat dissipation device 2h is as follows. When the semiconductor device 20 generates heat, the protrusion portion 775 of the soaking device 77 is at the position with relative high temperature, and the upper part of the soaking device 77 is at the position with relative low temperature. Meanwhile, the cooling substance 24 absorbs the heat of the semiconductor device 20 to become a vapor. The vapor may flow in the hollow accommodation space 774 to reach the upper part of the soaking device 77. As the temperature of the upper part of the soaking device 77 is relative low, when the vapor arrives at this end, it starts to proceed a condensation process. Thus, the heat is transmitted to the outside of the soaking device 77 with low temperature by the vapor through the shell body 772. Meanwhile, the vapor condenses into a liquid, and the liquid cooling substance 24 generated due to condensation flow back to the protrusion portion 775 under the effect of capillary pumping of the capillary structure 773, and then enter the holes 223. Such a circulation proceeds continuously, so as to improve the heat dissipation effect.

In this embodiment, the semiconductor device 20 is an LED device, and the thermal resistance thereof is 3.992° C./W. Compared with the prior art, this embodiment can effectively reduce the thermal resistance of the LED device (the semiconductor device 20). In other words, reduction of the thermal resistance indicates that the heat source generated by the LED device (the semiconductor device 20) can form more effective heat exchange with the external environment, thereby improving the heat dissipation efficiency.

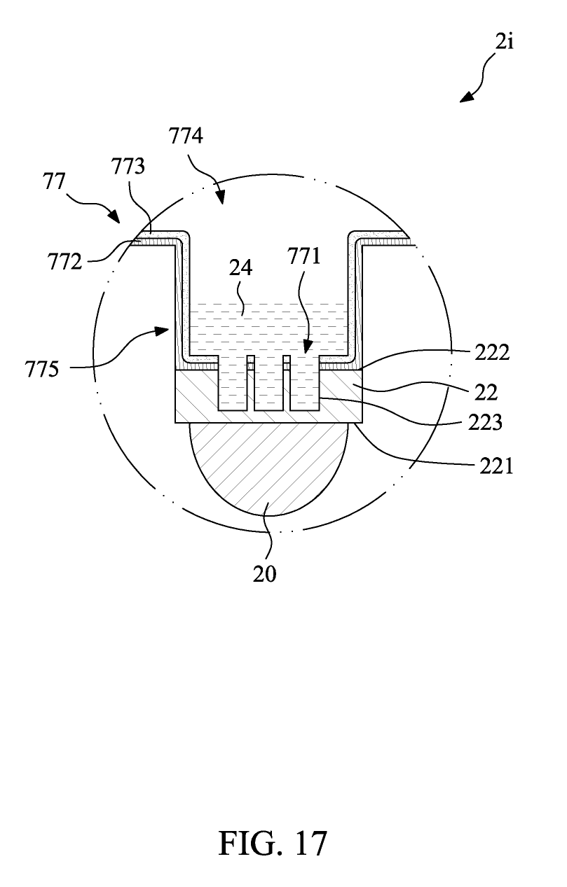

FIG. 17 is a schematic cross sectional view of another embodiment of the heat dissipation device according to the present invention. The heat dissipation device 2i of this embodiment is substantially similar to the heat dissipation device 2h of FIG. 15 and FIG. 16, and the same elements are designated with the same reference numerals. The difference between the heat dissipation device 2i of this embodiment and the heat dissipation device 2h of FIG. 15 and FIG. 16 lies in that, in this embodiment, the holes 223 are blind holes. That is, the holes 223 are not opened at the first surface 221 of the first substrate 22.

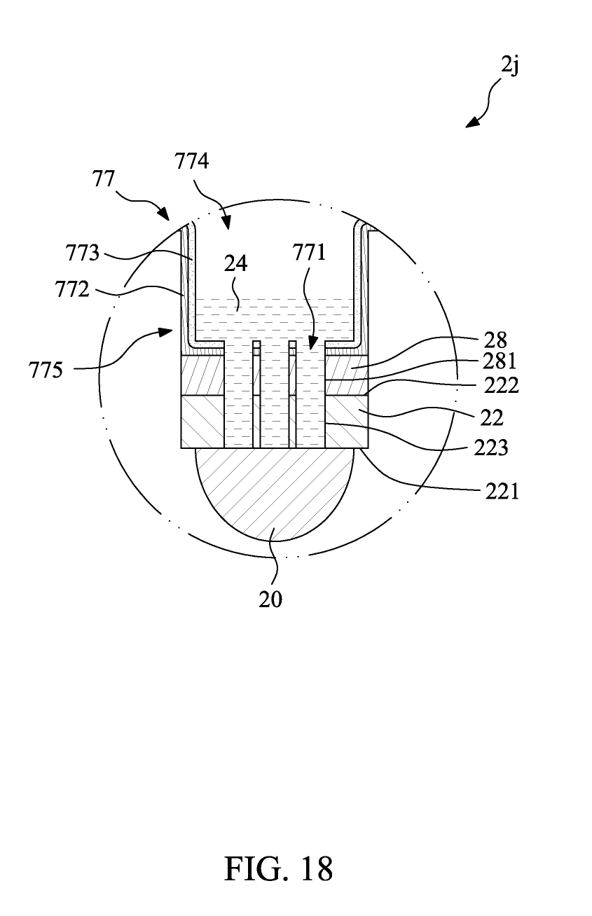

FIG. 18 is a schematic cross sectional view of another embodiment of the heat dissipation device according to the present invention. The heat dissipation device 2j of this embodiment is substantially similar to the heat dissipation device 2h of FIG. 15 and FIG. 16, and the same elements are designated with the same reference numerals. The difference between the heat dissipation device 2j of this embodiment and the heat dissipation device 2h of FIG. 15 and FIG. 16 lies in that, in this embodiment, the heat dissipation device 2j further comprises a second substrate 28. The material of the second substrate 28 is metal, such as aluminum, copper or ceramic The second substrate 28 is a heat dissipating substrate or a circuit board, and is disposed between the second surface 222 of the first substrate 22 and the soaking device 77. The second substrate 28 has at least one through hole 281. In this embodiment, the second substrate 28 has three through holes 281. The through holes 281 are in communication with the holes 223 of the first substrate 22 and the soaking device openings 771, so that the cooling substance 24 can flow into the holes 223 through the through holes 281.

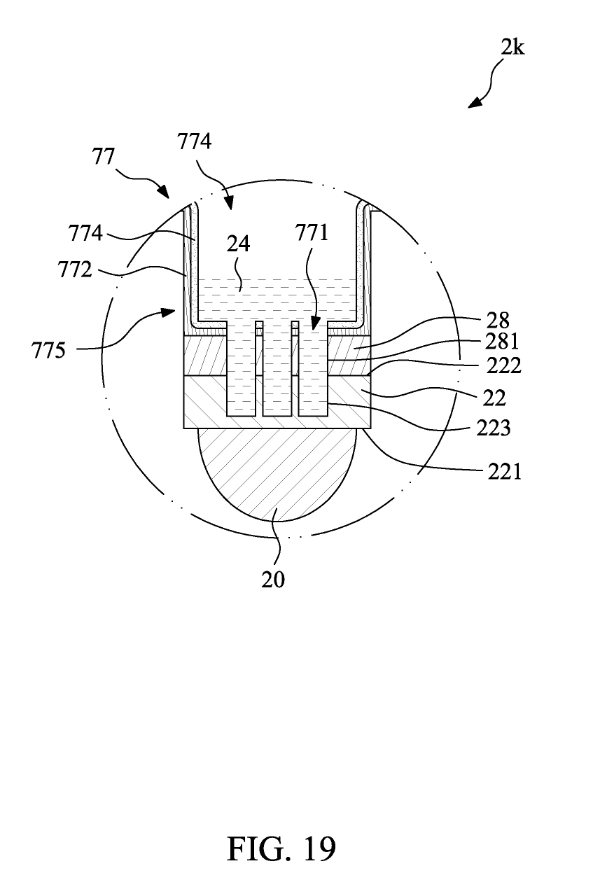

FIG. 19 is a schematic cross sectional view of another embodiment of the heat dissipation device according to the present invention. The heat dissipation device 2k of this embodiment is substantially similar to the heat dissipation device 2j of FIG. 18, and the same elements are designated with the same reference numerals. The difference between the heat dissipation device 2k of this embodiment and the heat dissipation device 2j of FIG. 18 lies in that, in this embodiment, the holes 223 are blind holes. That is, the holes 223 are not opened at the first surface 221 of the first substrate 22.

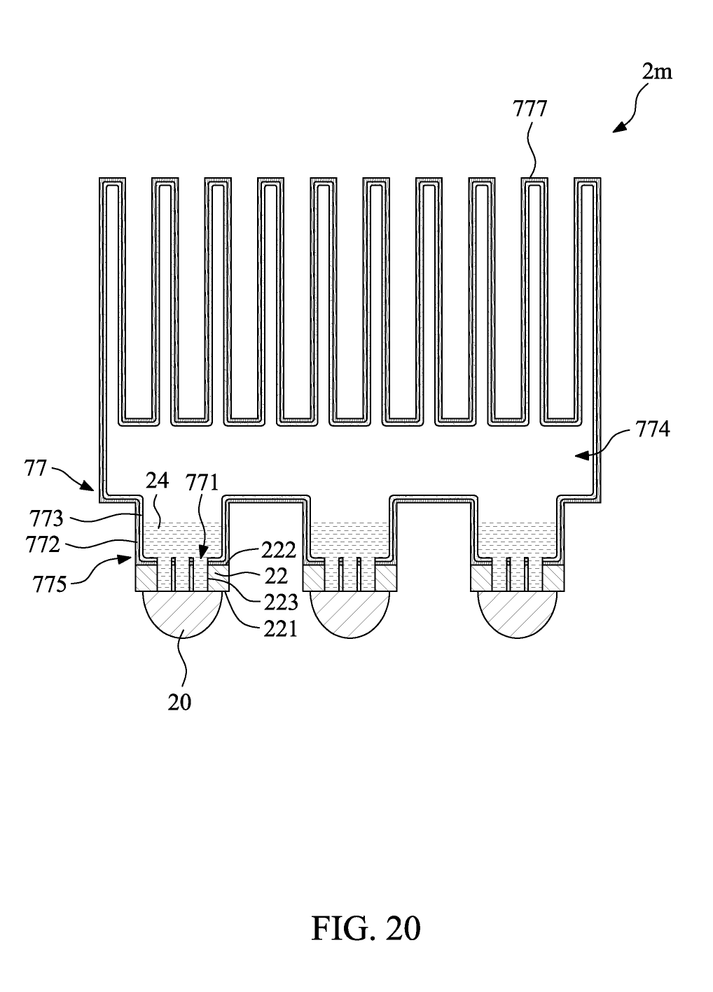

FIG. 20 is a schematic cross sectional view of another embodiment of the heat dissipation device according to the present invention. The heat dissipation device 2m of this embodiment is substantially similar to the heat dissipation device 2h of FIG. 15, and the same elements are designated with the same reference numerals. The difference between the heat dissipation device 2m of this embodiment and the heat dissipation device 2h of FIG. 15 lies in that, in this embodiment, the heat dissipation fins 776 (FIGS. 14 and 15) are replaced by a plurality of fin portions 777. The difference between the heat dissipation fins 776 and the fin portions 777 is that the fin portions 777 are parts of the soaking device 77. That is, the capillary structure 773 and the hollow accommodation space 774 extend into the fin portions 777. The soaking device 77 of this embodiment is finned heat pipe.

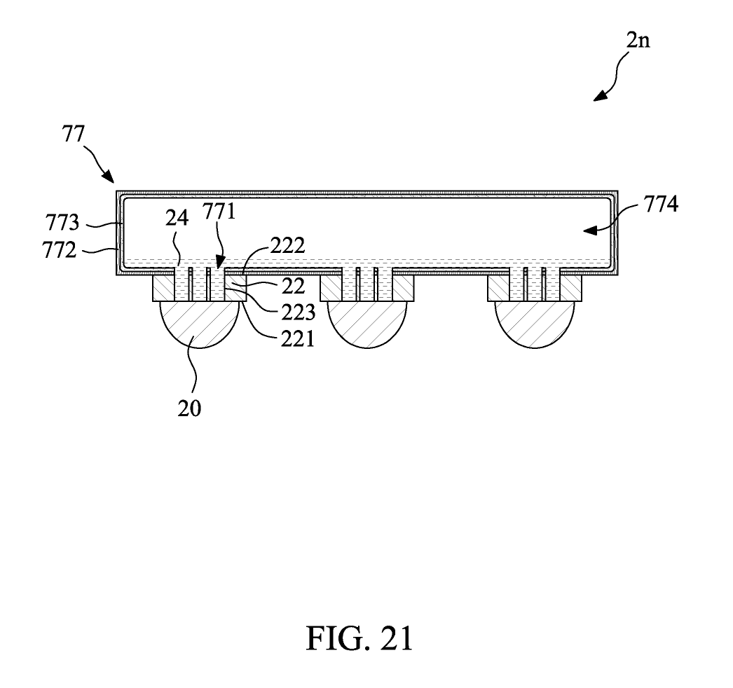

FIG. 21 is a schematic cross sectional view of another embodiment of the heat dissipation device according to the present invention. The heat dissipation device 2n of this embodiment is substantially similar to the heat dissipation device 2h of FIG. 15, and the same elements are designated with the same reference numerals. The difference between the heat dissipation device 2n of this embodiment and the heat dissipation device 2h of FIG. 15 lies in that, in this embodiment, the heat dissipation device 2n does not have the dissipation fins 776 (FIGS. 14 and 15), the protrusion portions 775 FIG. 15) and the fin portions 777 (FIG. 20). The soaking device 77 of this embodiment is flat heat pipe.

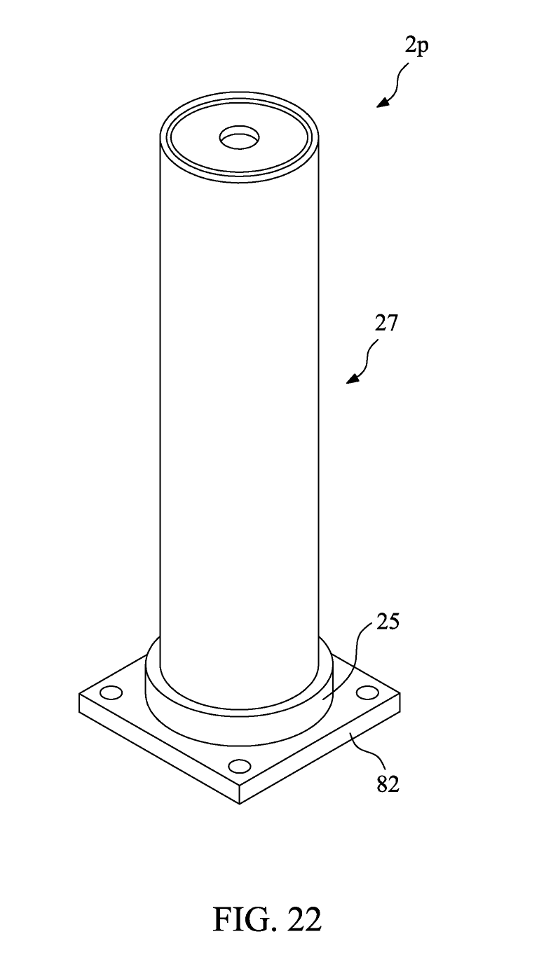

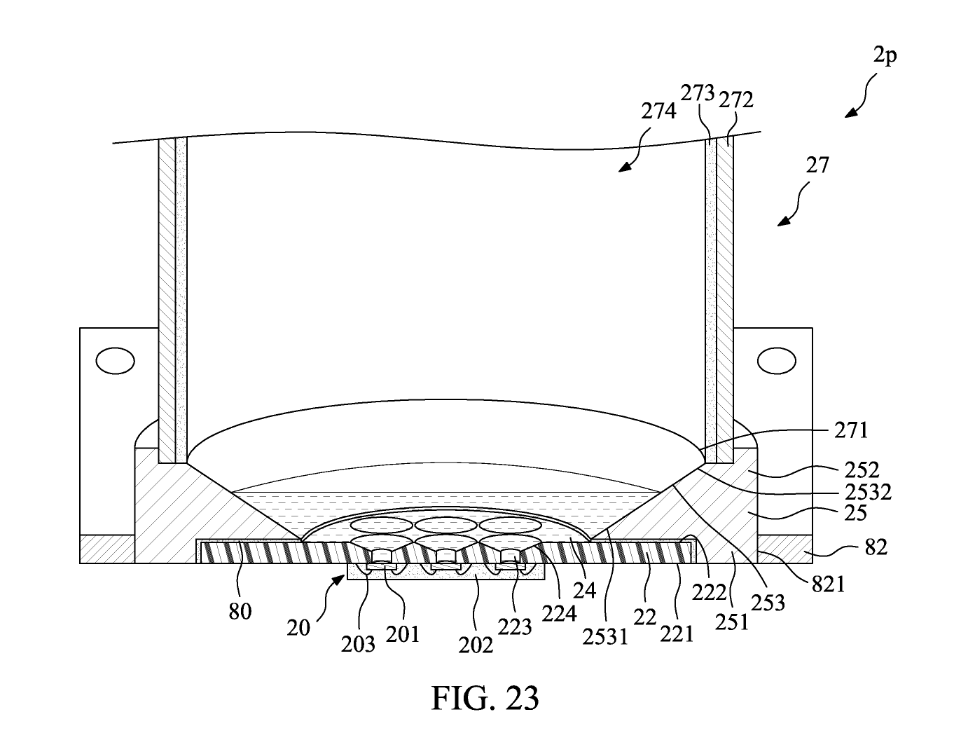

FIG. 22 is a schematic perspective view of an embodiment of the heat dissipation device according to the present invention. FIG. 23 is a schematic partially enlarged view of FIG. 22. The heat dissipation device 2p comprises the semiconductor device 20, the first substrate 22, at least one base 25, at least one soaking device 27, the cooling substance 24, a joint element 80 and a holder 82.

In this embodiment, the semiconductor device 20 is a light emitting diode (LED) device, which has a plurality of dice 201 and a molding compound 202, and is disposed on the first substrate 22.

In this embodiment, the first substrate 22 is a metal core PCB (MCPCB), and has a first surface 221, a second surface 222 and at least one hole 223. The semiconductor device 20 is located on the first surface 221 of the first substrate 22. That is, the dice 201 are attached to the first surface 221, and electrically connected to the first surface 221 by a plurality of bonding wires 203. The molding compound 202 encapsulates the dice 201 and the bonding wires 203.

The location of the hole 223 corresponds to the semiconductor device 20. Preferably, the upper end of the hole 223 has an upper notch 224, which is opened at the second surface 222 of the first substrate 22 and is cone-shaped. In this embodiment, the first substrate 22 has nine holes 223 arranged into a 3*3 matrix; however, in other embodiments, the first substrate 22 may have one hole 223 only. More specifically, each of the dice 201 corresponds to each of the holes 223, and the number of the holes 223 is equal to that of the dice 201.

The base 25 has a first end 251, a second end 252, and a through hole 253. The through hole 253 penetrates through the base 25, and is opened at the first end 251 and the second end 252 respectively. In this embodiment, the through hole 253 has a first opening 2531 and a second opening 2532 at the first end 251 and the second end 252 respectively. The sectional area of the first opening 2531 is less than that of the second opening 2532, so that the through hole 253 is cone-shaped.

The first substrate 22 is adjacent to the first end 251 of the base 25, and the sectional area of the first opening 2531 covers the holes 223, so that the holes 223 are in communication with the through hole 253. In this embodiment, the joint element 80 is located between the first substrate 22 and the base 25, for joining the first substrate 22 and the base 25. The joint element 80 is a cold flux for filling pores, a ceramic cold flux or a fluorescent powder-doped package gel. In addition to the joining function, the joint element 80 also has a sealing function, which can prevent the cooling substance 24 form leaking out.

The soaking device 27 is adjacent to the second end 252 of the base 25 and has a soaking device opening 271. The soaking device opening 271 is in communication with the through hole 253. In this embodiment, the soaking device 27 is fixed to the second end 252 of the base 25 by means of argon welding. The cooling substance 24 is located in the hole 223, and absorbs heat of the semiconductor device 20, so as to form a vapor to flow in the soaking device 27. The soaking device 27 includes a shell body 272 and a capillary structure 273. The capillary structure 273 is located at inner sidewalls of the shell body 272 to define a hollow accommodation space 274. Preferably, the material of the shell body 272 is metal (for example, brass, nickel, stainless steel, tungsten or other alloys), and the capillary structure 273 is a copper mesh, copper power sinter or trench.

The soaking device opening 271 is in communication with the hollow accommodation space 274, so that the vapor formed by the cooling substance 24 can flow in the hollow accommodation space 274 through the soaking device opening 271, thereby proceeding heat exchange with the external environment through the shell body 272, and finally condenses into the liquid state cooling substance 24. The condensed liquid cooling substance 24 flows through the through hole 253 of the base 25 via the capillary structure 273 and then flows back to the holes 223, so as to continuously take away the heat generated by the semiconductor device 20 and form a heat dissipation circulation.

The holder 82 has a central through hole 821, for accommodating the base 25. In this embodiment, the material of the holder 82 and the base 25 is metal (for example, brass, nickel, stainless steel, tungsten or other alloys), and the holder 82 is fixedly to the base 25. However, in other embodiments, the holder 82 and the base 25 are integrally formed.

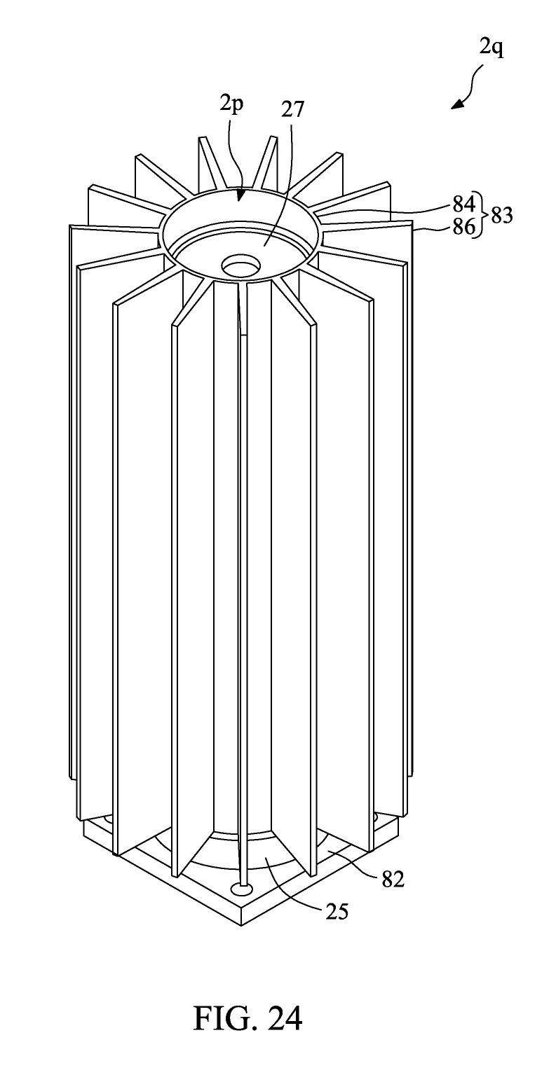

FIG. 24 is a schematic perspective view of another embodiment of the heat dissipation device according to the present invention. The heat dissipation device 2q of this embodiment is substantially similar to the heat dissipation device 2p of FIG. 22 and FIG. 23, and the same elements are designated with the same reference numerals. The difference between the heat dissipation device 2q of this embodiment and the heat dissipation device 2p of FIG. 22 and FIG. 23 lies in that, in this embodiment, the heat dissipation device 2q further comprises a heat dissipation element 83 which has a center pipe 84 and a plurality of heat dissipation fins 86. The soaking device 27 is inserted into the center pipe 84. Preferably, the center pipe 84 contacts the soaking device 27. The heat dissipation fins 86 extend outward from the center pipe 84 radially, and the center pipe 84 and the heat dissipation fins 86 are integrally formed.

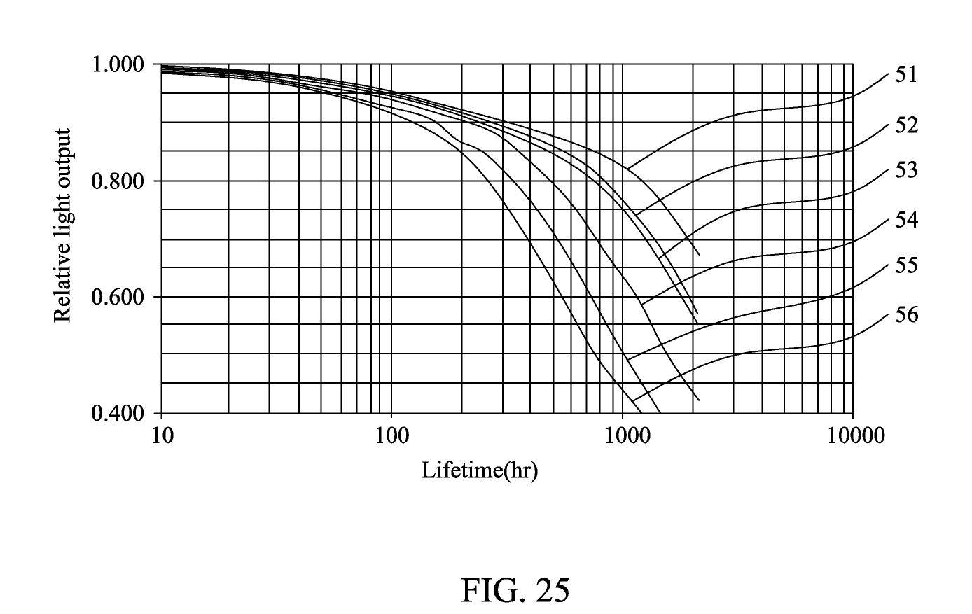

FIG. 25 is a diagram illustrating a relation between relative light output and lifetime of the LED device at different junction temperatures. The junction temperature refers to the temperature of a contact surface (namely the first surface 221) between the dice 201 and the first substrate 22. The light output of the LED device may be attenuated with time, and the relative light output is the ratio of light output to initial light output. In FIG. 25, a curve 51 denotes the junction temperature of 69° C., a curve 52 denotes the junction temperature of 79° C., a curve 53 denotes the junction temperature of 85° C., a curve 54 denotes the junction temperature of 96° C., a curve 55 denotes the junction temperature of 107° C., and a curve 56 denotes the junction temperature of 115° C. As shown in FIG. 25, when the relative light output is the same, the lower junction temperature causes the longer lifetime of the LED device.

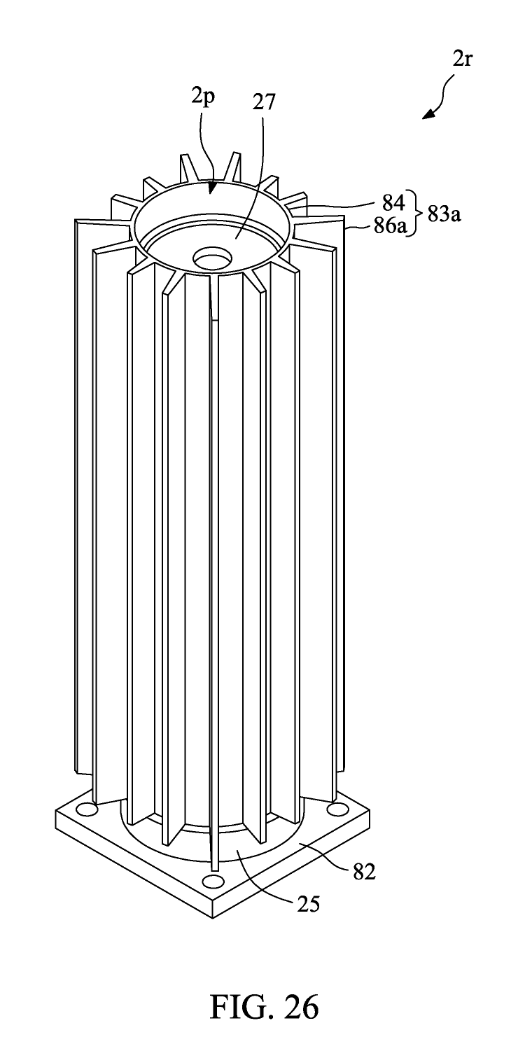

FIG. 26 is a schematic perspective view of another embodiment of the heat dissipation device according to the present invention. The heat dissipation device 2r of this embodiment is substantially similar to the heat dissipation device 2q of FIG. 24, and the same elements are designated with the same reference numerals. The difference between the heat dissipation device 2r of this embodiment and the heat dissipation device 2q of FIG. 24 lies in that, the outward extending widths of the heat dissipation fins 86 of the heat dissipation element 83 of the heat dissipation device 2q in FIG. 24 extend outward are equal, so as to form a round appearance at the periphery; conversely, in this embodiment, the outward extending widths of the heat dissipation fins 86a of the heat dissipation element 83a of the heat dissipation device 2r are not equal, so as to form a rectangular appearance at the periphery.

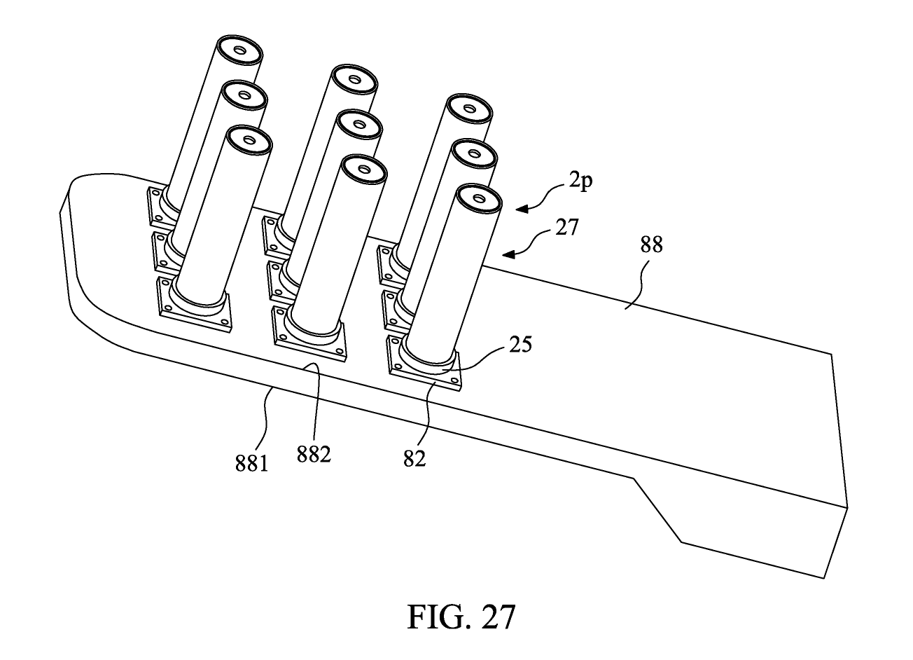

FIG. 27 is a schematic view illustrating the heat dissipation device of FIG. 22 being assembled on a receiving plate. The receiving plate 88 has a first surface 881, a second surface 882, and a plurality of openings (not shown). The openings penetrate through the receiving plate 88. A plurality of heat dissipation devices 2p (FIG. 22) is fixed (for example, by screwing) to the second surface 882 of the receiving plate 88 by using the holder 82 thereof. The openings correspond to the semiconductor devices 20 of the heat dissipation devices 2p, so as to expose the semiconductor devices 20. Thereby, when the semiconductor devices 20 are LED devices, their brightness can be increased, so as to be used, for example, as road lamps. In this embodiment, the heat dissipation devices 2p are arranged in a 3*3 array; however, in other embodiments, the heat dissipation devices 2p may be arranged in other pattern as required.

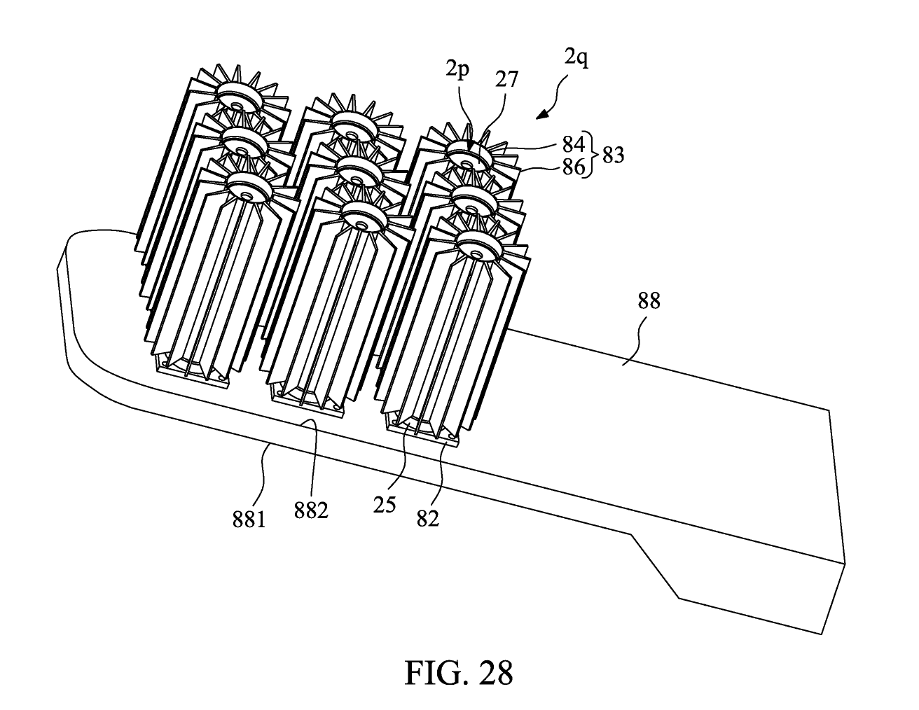

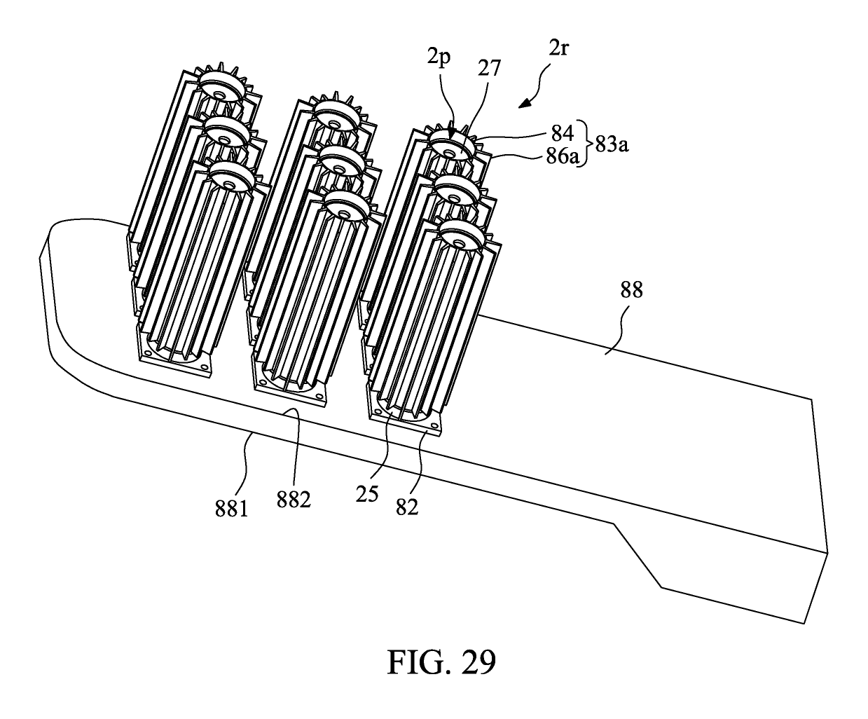

FIG. 28 is a schematic view illustrating the heat dissipation device of FIG. 24 being assembled on a receiving plate. In this embodiment, a plurality of heat dissipation devices 2q (FIG. 24) is fixed (for example, by screwing) to the second surface 882 of the receiving plate 88 by using the holder 82 thereof. The openings of the receiving plate 88 correspond to the semiconductor devices 20 of the heat dissipation devices 2q, so as to expose the semiconductor devices 20. In this embodiment, the heat dissipation devices 2q are arranged in a 3*3 array; however, in other embodiments, the heat dissipation devices 2q may be arranged in other pattern as required.

FIG. 29 is a schematic view illustrating the heat dissipation device of FIG. 26 being assembled on a receiving plate. In this embodiment, a plurality of heat dissipation devices 2r (FIG. 26) is fixed (for example, by screwing) to the second surface 882 of the receiving plate 88 by using the holder 82 thereof. The openings of the receiving plate 88 correspond to the semiconductor devices 20 of the heat dissipation devices 2r, so as to expose the semiconductor devices 20. In this embodiment, the heat dissipation devices 2r are arranged in a 3*3 array; however, in other embodiments, the heat dissipation devices 2r may be arranged in other pattern as required.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A heat dissipation device, comprising:
at least one semiconductor device;
at least one first substrate having a first surface, a second surface and at least one hole, wherein the at least one semiconductor device is located on the first surface of the at least one first substrate, and the at least one hole is opened at the second surface of the at least one first substrate and corresponds to the at least one semiconductor device; and
a cooling substance used for flowing in the at least one hole and taking away heat from the at least one semiconductor device, wherein the cooling substance is in contact with the at least one first substrate.

2. The heat dissipation device of claim 1, wherein the at least one hole is further opened at the first surface of the first substrate, so that the cooling substance contacts the at least one semiconductor device.

3. The heat dissipation device of claim 1, wherein the heat dissipation device comprises a plurality of semiconductor devices located on the first substrate.

4. The heat dissipation device of claim 1, wherein the at least one hole is blind hole.

5. The heat dissipation device of claim 1, further comprising a second substrate disposed on the second surface of the first substrate, wherein the second substrate has at least one through hole in communication with the at least one hole of the at least one first substrate, so that the cooling substance flows into the at least one hole through the at least one through hole.

6. The heat dissipation device of claim 1, further comprising at least one container for accommodating the cooling substance, wherein the at least one container has an opening, the at least one hole of the at least one first substrate is in communication with the opening, so that the cooling substance flows into the at least one hole through the opening of the container.

7. The heat dissipation device of claim 6, further comprising:
a circulation pipeline connecting the container, so that the cooling substance flows therein;
a pump located on the circulation pipeline, for providing kinetic energy required by the cooling substance during flowing; and
a plurality of heat dissipation fins located on the circulation pipeline, for dissipating heat of the cooling substance.

8. The heat dissipation device of claim 6, further comprising a connection pipeline and a pump, wherein the number of the semiconductor device is plural, the number of the first substrate is plural, and the number of the container is plural, each of the semiconductor devices is disposed on each of the first substrates, each of the first substrates is disposed on each of the containers, the connection pipeline connects the containers, and the pump is located on the connection pipeline for providing kinetic energy required by the cooling substance during flowing.

9. The heat dissipation device of claim 6, further comprising:
a base plate having a center groove, an inlet slot and an outlet slot, wherein the inlet slot and the outlet slot are in communication with the center groove.

10. The heat dissipation device of claim 6, wherein the container is a base plate having a bending long trench, and the heat dissipation device comprises a plurality of semiconductor devices arranged on the first substrate by means of array.

11. The heat dissipation device of claim 1, further comprising at least one soaking device, wherein the at least one soaking device comprises at least one soaking device opening in communication with the at least one hole; the cooling substance absorbs the heat of the at least one semiconductor device so as to form a vapor to flow in the at least one soaking device.

12. The heat dissipation device of claim 11, wherein the at least one soaking device comprises a shell body and a capillary structure, the capillary structure is located at inner sidewalls of the shell body to define a hollow accommodation space, the at least one soaking device opening penetrates through the shell body and the capillary structure to be in communication with the hollow accommodation space, so that the vapor formed by the cooling substance flows in the hollow accommodation space, thereby forming heat exchange with the external environment through the shell body, and condenses into liquid state cooling substance.

13. The heat dissipation device of claim 12, wherein the at least one soaking device further comprises at least one protrusion portion, the at least one protrusion portion corresponds to the at least one first substrate and has the at least one soaking device opening, the capillary structure and the hollow accommodation space extend into the at least one protrusion portion.

14. The heat dissipation device of claim 12, wherein the at least one soaking device further comprises a plurality of fin portions, the capillary structure and the hollow accommodation space extend into the fin portions.

15. The heat dissipation device of claim 12, further comprises a plurality of heat dissipation fins connected to an outer sidewall of the shell body of the at least one soaking device.

16. The heat dissipation device of claim 12, wherein the material of the shell body is metal, and the capillary structure is copper mesh, copper power sinter or trench.

17. The heat dissipation device of claim 11, further comprising at least one base having a through hole, wherein the through hole penetrates through the at least one base, the first substrate is adjacent to the at least one base, the at least one hole is in communication with the through hole;
the at least one soaking device is adjacent to the at least one base, and the at least one soaking device opening is in communication with the through hole.

18. The heat dissipation device of claim 17, wherein the at least one base further has a first end and a second end, the through hole is opened at the first end and the second end respectively, the first substrate is adjacent to the first end of the at least one base, and the at least one soaking device is adjacent to the second end of the at least one base.

19. The heat dissipation device of claim 17, further comprising at least one heat dissipation element having a center pipe and a plurality of heat dissipation fins, wherein the at least one soaking device is inserted into the center pipe, the heat dissipation fins extend outward from the center pipe, and the center pipe and the heat dissipation fins are integrally formed.

20. The heat dissipation device of claim 17, further comprising at least one holder and a receiving plate, wherein the at least one holder has a central through hole for accommodating the at least one base, the at least one holder is fixed to the receiving plate, and the receiving plate has at least one opening to expose the at least one semiconductor device.
